(19) United States
(12) Patent Application Publication
(10) Pub. No.: US 2025/0149490 A1
(43) Pub. Date: May 8, 2025

(54) SEMICONDUCTOR PACKAGE

(71) Applicant: SAMSUNG ELECTRONICS CO., LTD., SUWON-SI (KR)

(72) Inventors: Wonhee Lee, Suwon-si (KR); Yunrae Cho, Suwon-si (KR)

(21) Appl. No.: 18/830,785

(22) Filed: Sep. 11, 2024

(30) Foreign Application Priority Data
Nov. 2, 2023 (KR) 10-2023-0150288

(51) Int. Cl. H01L 23/00; H01L 23/31; H01L 23/498; H01L 25/065; H10B 80/00

(52) U.S. Cl. CPC H01L 24/17; H01L 23/3135; H01L 24/13; H01L 24/14; H01L 24/16; H01L 25/0657; H01L 23/498; H01L 2224/13017; H01L 2224/13082; H01L 2224/1403; H01L 2224/14051; H01L 2224/16146; H01L 2224/16147; H01L 2224/16227; H01L 2224/17181; H01L 2224/17517; H01L 2225/06541; H01L 2225/06565; H10B 80/00

(57) ABSTRACT

A semiconductor package includes a plurality of semiconductor chips stacked in a first direction, a plurality of chip connection terminals disposed between two semiconductor chips disposed adjacent to each other in the first direction among the plurality of semiconductor chips and electrically connecting the two adjacent semiconductor chips, and a plurality of chip support structures disposed between the two adjacent semiconductor chips. The plurality of chip support structures do not electrically connect the two adjacent semiconductor chips, and are spaced apart from the plurality of chip connection terminals in a second direction crossing the first direction. A thickness of each of the plurality of chip support structures is greater than a thickness of each of the plurality of chip connection terminals.

### CROSS-REFERENCE TO RELATED APPLICATION

This application claims priority under 35 U.S.C. § 119 to Korean Patent Application No. 10-2023-0150288, filed on Nov. 2, 2023 in the Korean Intellectual Property Office, the disclosure of which is incorporated by reference herein in its entirety.

### TECHNICAL FIELD

Embodiments of the inventive concept relate to a semiconductor package, and more particularly, to a semiconductor package including a plurality of vertically stacked semiconductor chips.

### DISCUSSION OF RELATED ART

As the electronics industry rapidly develops, semiconductor packages mounted on electronic products have been utilized to provide high performance and include various functions, and thus, semiconductor packages including a plurality of semiconductor chips have been proposed.

In addition, to reduce the size of semiconductor packages including a plurality of semiconductor chips, semiconductor packages in which a plurality of semiconductor chips are vertically stacked have been developed.

### SUMMARY

Embodiments of the inventive concept provide a semiconductor package including a plurality of vertically stacked semiconductor chips having structural reliability.

According to an embodiment of the inventive concept, a semiconductor package includes a plurality of semiconductor chips stacked in a first direction, a plurality of chip connection terminals disposed between two semiconductor chips disposed adjacent to each other in the first direction among the plurality of semiconductor chips and electrically connecting the two adjacent semiconductor chips, and a plurality of chip support structures disposed between the two adjacent semiconductor chips. The plurality of chip support structures do not electrically connect the two adjacent semiconductor chips, and are spaced apart from the plurality of chip connection terminals in a second direction crossing the first direction. A thickness of each of the plurality of chip support structures is greater than a thickness of each of the plurality of chip connection terminals.

According to an embodiment of the inventive concept, a semiconductor package includes a package substrate including a package base insulating layer, a lower solder resist layer covering a lower surface of the package base insulating layer, and an upper solder resist layer covering an upper surface of the package base insulating layer, and a plurality of semiconductor chips each including a substrate, a front protective layer disposed on a lower surface of the substrate, and a rear protective layer disposed on an upper surface of the substrate. The plurality of semiconductor chips includes a first semiconductor chip disposed on the package substrate and a plurality of second semiconductor chips sequentially stacked on the first semiconductor chip. The semiconductor package further includes a plurality of first chip connection terminals disposed between the package substrate and the first semiconductor chip and electrically connecting the package substrate to the first semiconductor chip, and a plurality of first chip support structures disposed between the package substrate and the first semiconductor chip. The plurality of first chip support structures are spaced apart from the plurality of first chip connection terminals in a second direction and extend into the upper solder resist layer. The semiconductor package further includes a plurality of second chip connection terminals disposed between two semiconductor chips disposed adjacent to each other in a first direction among the plurality of semiconductor chips. The plurality of second chip connection terminals electrically connect the two adjacent semiconductor chips, and the second direction crosses the first direction. The semiconductor package further includes a plurality of second chip support structures disposed between the two adjacent semiconductor chips. The plurality of second chip support structures extend into the rear protective layer included in a lower semiconductor chip among the two adjacent semiconductor chips.

According to an embodiment of the inventive concept, a semiconductor package includes a package substrate including a package base insulating layer, a plurality of package upper pads disposed on an upper surface of the package base insulating layer, a plurality of package lower pads disposed on a lower surface of the package base insulating layer, a plurality of connection pads electrically connecting the plurality of package upper pads to the plurality of package lower pads, an upper solder resist layer covering the upper surface of the package base insulating layer and not covering at least a portion of an upper surface of each of the plurality of package upper pads, and a lower solder resist layer covering the lower surface of the package base insulating layer and not covering at least a portion of a lower surface of each of the plurality of package lower pads. The semiconductor package further includes a plurality of semiconductor chips including a first semiconductor chip and a plurality of second semiconductor chips sequentially stacked on the package substrate. The first semiconductor chip and the plurality of second semiconductor chips each include a substrate, a plurality of rear connection pads disposed on an upper surface of the substrate, a plurality of front connection pads disposed on a lower surface of the substrate, a plurality of through-electrodes vertically penetrating through at least a portion of the substrate and electrically connecting the plurality of rear connection pads to the plurality of front connection pads, a front protective layer disposed on the lower surface of the substrate and not covering at least a portion of a lower surface of each of the plurality of front connection pads, and a rear protective layer disposed on the upper surface of the substrate and not covering at least a portion of an upper surface of each of the plurality of rear connection pads. The semiconductor package further includes a plurality of first chip connection terminals disposed between the plurality of package upper pads of the package substrate and the plurality of front connection pads of the first semiconductor chip, and a plurality of first chip support structures disposed between the package substrate and the first semiconductor chip. The plurality of first chip support structures are spaced apart from the plurality of chip connection terminals in a second direction, extend into the upper solder resist layer, and do not penetrate through the upper solder resist layer. The semiconductor package further includes a plurality of second chip connection terminals disposed between two semiconductor chips disposed adjacent to each other in a first direction among the plurality of semiconductor chips and disposed between the plurality of rear connection pads and the plurality of front connection pads facing each other included in the two adjacent semiconductor chips. The second direction crosses the first direction. The semiconductor package further includes a plurality of second chip support structures disposed between the two adjacent semiconductor chips. The plurality of second chip support structures extend into the rear protective layer included in a lower semiconductor chip among the two adjacent semiconductor chips and do not penetrate through the rear protective layer.

### BRIEF DESCRIPTION OF THE DRAWINGS

The above and other features of the present inventive concept will become more apparent by describing in detail embodiments thereof with reference to the accompanying drawings, in which:

FIG. 1 is a cross-sectional view of a semiconductor package according to an embodiment;

FIGS. 2A to 2D are enlarged cross-sectional views of a semiconductor package according to embodiments;

FIGS. 3A and 3B are enlarged cross-sectional views of a semiconductor package according to an embodiment;

FIGS. 4A and 4B are enlarged cross-sectional views of a semiconductor package according to an embodiment;

FIGS. 5A and 5B are enlarged cross-sectional views of a semiconductor package according to an embodiment;

FIGS. 6A and 6B are enlarged cross-sectional views of a semiconductor package according to an embodiment;

FIG. 7 is a cross-sectional view of a semiconductor package according to an embodiment;

FIG. 8 is a cross-sectional view of a semiconductor package according to an embodiment;

FIGS. 9A and 9B are enlarged cross-sectional views of a semiconductor package according to an embodiment;

FIG. 10 is a cross-sectional view of a semiconductor package according to an embodiment; and

FIGS. 11, 12, 13A-13D, 14 and 15A-5D are cross-sectional views and enlarged cross-sectional views illustrating a method of manufacturing a semiconductor package according to embodiments.

### DETAILED DESCRIPTION OF THE EMBODIMENTS

Embodiments of the present inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

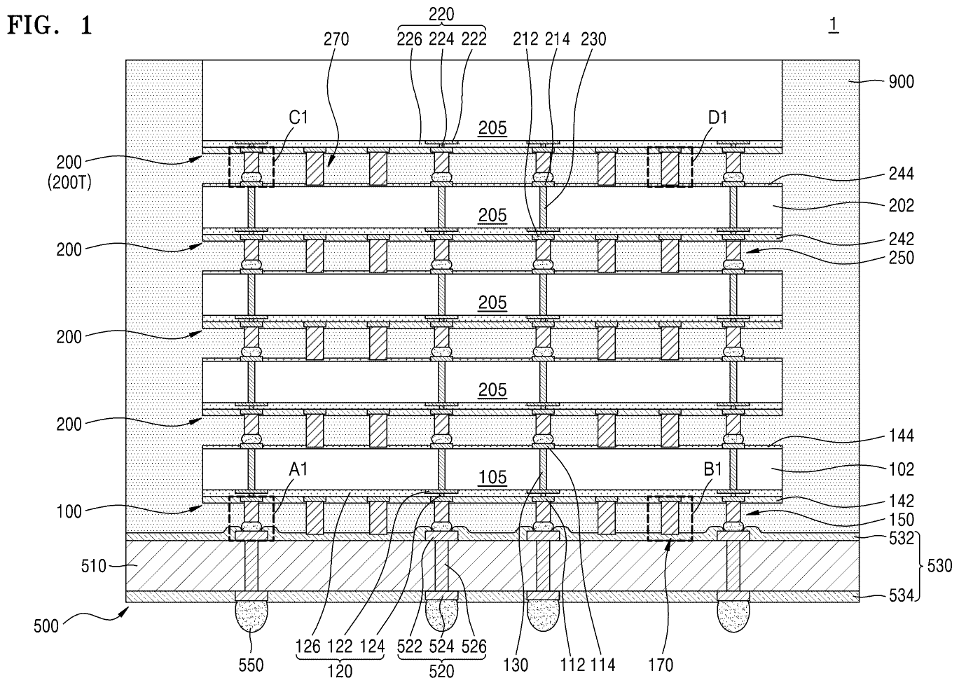

FIG. 1 is a cross-sectional view of a semiconductor package 1 according to an embodiment.

Referring to FIG. 1, the semiconductor package 1 may include a package substrate 500, a first semiconductor chip 100 attached to the package substrate 500, a plurality of second semiconductor chips 200 vertically stacked on the first semiconductor chip 100, and a molding layer 900 surrounding the first semiconductor chip 100 and the second semiconductor chips 200 on the package substrate 500.

The package substrate 500 may be a printed circuit board (PCB). The package substrate 500 may be a double-sided PCB, but is not limited thereto. For example, the package substrate 500 may be a multi-layer PCB. The package substrate 500 may include a package base insulating layer 510, a plurality of package conductive patterns 520, and a solder resist layer 530.

The package base insulating layer 510 may include at least one of, for example, phenol resin, epoxy resin, and polyimide. The package base insulating layer 510 may include, for example, frame retardant 4 (FR-4), tetrafunctional epoxy, polyphenylene ether, epoxy/polyphenylene oxide, bismaleimide triazine (BT), thermount, cyanate ester, polyimide, and liquid crystal polymer. In some embodiments, the package base insulating layer 510 may include, for example, polyester (PET), polyester telephthalate, fluorinated ethylene propylene (FEP), resin-coated paper, liquid polyimide resin, polyethylene naphthalate (PEN) film, etc. In some embodiments, the package base insulating layer 510 may be formed by stacking a plurality of base layers.

The package conductive patterns 520 may include copper (Cu) or an alloy containing copper (Cu). The package conductive patterns 520 may include a plurality of package upper pads 522, a plurality of package lower pads 524, and a plurality of connection patterns 526. The package upper pads 522 may be disposed on an upper surface of the package base insulating layer 510, and the package lower pads 524 may be disposed on a lower surface of the package base insulating layer 510. The connection patterns 526 may electrically connect the package upper pads 522 to the package lower pads 524. In FIG. 1, each of the connection patterns 526 is shown as a via pattern penetrating through the package base insulating layer 510. However, this is an example provided for convenience of illustration, and the inventive concept is not limited thereto. For example, the connection patterns 526 may include a plurality of line patterns and a plurality of via patterns. The line patterns may extend along the upper and/or lower surfaces of the package base insulating layer 510. When the package base insulating layer 510 includes the base layers, the line patterns may extend along the upper and/or lower surfaces of the base layers.

The via patterns may fill at least a portion of the via through-holes penetrating through the package base insulating layer 510 or at least one of the base layers and connect two of the package upper pads 522, the package lower pads 524, and the line patterns disposed at different vertical levels. In some embodiments, the via patterns may fill all of the via through-holes. In some embodiments, the via patterns may be formed to cover inner walls of the via through-holes and fill a portion of the via through-holes, and a plurality of via filling insulating layers may cover the via patterns and fill the via through-holes. For example, the via through-holes may be completely filled by the via patterns and the via filling insulating layers.

The package upper pads 522, the package lower pads 524, and the line patterns may each include, for example, electrolytically deposited (ED) copper foil, rolled-annealed (RA) copper foil, stainless steel foil, aluminum foil, ultra-thin copper foil, sputtered copper, copper alloys, etc. In some embodiments, each of the package upper pads 522 and the package lower pads 524 may include, for example, copper, nickel, stainless steel, or beryllium copper. For example, each of the package upper pads 522 and the package lower pads 524 may include plated copper. In some embodiments, Ni/Au, etc. may be included in a surface portion of each of the package upper pads 522 and the package lower pads 524 on the opposite side of the package base insulating layer 510.

Each of the via patterns may have a structure in which copper (Cu) or an alloy including copper (Cu) is stacked on a seed layer including, for example, copper (Cu), titanium (Ti), titanium tungsten (TiW), titanium nitride (TiN), tantalum (Ta), tantalum nitride (TaN), chromium (Cr), Cu/Ti in which copper (Cu) is stacked on titanium (Ti), or Cu/TiW in which copper is staked on titanium tungsten, but is not limited thereto.

The package substrate 500 may include the solder resist layer 530 disposed on the upper and lower surfaces of the package substrate 500. The solder resist layer 530 may include the upper solder resist layer 532 disposed on the upper surface of the package substrate 500 to cover the upper surface of the package base insulating layer 510, and the lower solder resist layer 534 disposed on the lower surface of the package substrate 500 to cover the lower surface of the package base insulating layer 510. At least a portion of each of the package upper pads 522 disposed on the upper surface of the package base insulating layer 510 may be exposed to the upper surface of the package substrate 500 without being covered by the upper solder resist layer 532, and at least a portion of each of the package lower pads 524 disposed on the lower surface of the package base insulating layer 510 may be exposed to the lower surface of the package substrate 500 without being covered by the lower solder resist layer 534. In some embodiments, among the line patterns, line patterns disposed on the upper surface of the package base insulating layer 510 may be covered by the upper solder resist layer 532 and are not exposed to the upper surface of the package substrate 500, and line patterns disposed on the lower surface of the package base insulating layer 510 may be covered by the lower solder resist layer 534 and are not exposed to the lower surface of the package substrate 500. For example, each of the upper solder resist layer 532 and the lower solder resist layer 534 may have a thickness of about 15 μm to about 25 μm.

A plurality of package connection terminals 550 may be attached to the package lower pads 524 of the semiconductor packages 1. The package connection terminals 550 may function as external connection terminals of the semiconductor package 1. The package connection terminals 550 may electrically connect the semiconductor package 1 to an external device. In some embodiments, the package connection terminals 550 may include, for example, bumps, solder balls, etc. A plurality of first chip connection terminals 150 may be attached to the package upper pads 522.

In FIG. 1, the semiconductor package 1 is shown as including one first semiconductor chip 100 and four second semiconductor chips 200, but the inventive concept is not limited thereto. For example, in some embodiments, the semiconductor package 1 may include two or more second semiconductor chips 200. In some embodiments, the semiconductor package 1 may include a quantity of second semiconductor chips 200 in a multiple of 4. The second semiconductor chips 200 may be sequentially stacked on the first semiconductor chip 100 in a first direction (e.g., a vertical direction).

In some embodiments, among the second semiconductor chips 200, the uppermost second semiconductor chip 200T disposed farthest from the first semiconductor chip 100 does not include a second rear connection pad 214 and a second through-electrode 230. In some embodiments, among the second semiconductor chips 200, a thickness of the uppermost second semiconductor chip 200T disposed farthest from the first semiconductor chip 100 may have a value greater than that of the other second semiconductor chips 200.

In this specification, a relation between the first semiconductor chip 100 and the second semiconductor chips 200 refers to relations between each of the semiconductor chips including the first semiconductor chip 100 and the second semiconductor chips 200. That is, in this specification, the relation between the first semiconductor chip 100 and the second semiconductor chips 200 refers to a relation between the first semiconductor chip 100 and the lowermost second semiconductor chip 200 among the second semiconductor chips 200 and a relation between two second semiconductor chips 200 disposed adjacent to each other among the second semiconductor chips 200. The first semiconductor chip 100 and the second semiconductor chips 200 may together be referred to as a plurality of semiconductor chips. The semiconductor chips may be stacked in the vertical direction. The first semiconductor chip 100 may be the lowermost semiconductor chip among the semiconductor chips, and the second semiconductor chips 200 may be the other semiconductor chips excluding the lowermost semiconductor chip among the semiconductor chips. In addition, among the semiconductor chips, two semiconductor chips disposed adjacent to each other in the vertical direction may be referred to as a first semiconductor chip and a second semiconductor chip or may be referred to as a lower semiconductor chip and an upper semiconductor chip.

In some embodiments, a horizontal width and area of the first semiconductor chip 100 may be substantially the same as a horizontal width and area of each of the second semiconductor chips 200. For example, the edge of each of the second semiconductor chips 200 may be aligned in the vertical direction with the edge of the first semiconductor chip 100. The second semiconductor chips 200 may overlap the first semiconductor chip 100 in the vertical direction. In some embodiments, the horizontal width and area of the first semiconductor chip 100 may be greater than the horizontal width and area of each of the second semiconductor chips 200. For example, in some embodiments, the edge of each of the second semiconductor chips 200 is not aligned with the edge of the first semiconductor chip 100 in the vertical direction, so that the edge of each of the second semiconductor chips 200 may be spaced apart from the edge of the first semiconductor chip 100 planarly.

The first semiconductor chip 100 includes a first substrate 102, a first interconnection layer 120, a plurality of first through-electrodes 130, a first front protective layer 142, and a first rear protective layer 144. A plurality of first front connection pads 112 may be disposed on the lower surface of the first semiconductor chip 100, and a plurality of first rear connection pads 114 may be disposed on the upper surface of the first semiconductor chip 100. The second semiconductor chip 200 includes a second substrate 202, a second interconnection layer 220, a plurality of second through-electrodes 230, a second front protective layer 242, and a second rear protective layer 244. A plurality of second front connection pads 212 may be disposed on the lower surface of the second semiconductor chip 200, and a plurality of second rear connection pads 214 may be disposed on the upper surface of the second semiconductor chip 200. Each of the first front connection pad 112, the first rear connection pad 114, the second front connection pad 212, and the second rear connection pad 214 may include a metal, such as, for example, aluminum, copper, or tungsten.

The first substrate 102 may be referred to as a substrate of the first semiconductor chip 100, the first front connection pad 112 may be referred to as a front connection pad of the first semiconductor chip 100, the first rear connection pad 114 may be referred to as a rear connection pad of the first semiconductor chip 100, the first interconnection layer 120 may be referred to as an interconnection layer of the first semiconductor chip 100, the first through-electrode 130 may be referred to as a through-electrode of the first semiconductor chip 100, the first front protective layer 142 may be referred to as a front protective layer of the first semiconductor chip 100, and the first rear protective layer 144 may be referred to as a rear protective layer of the first semiconductor chip 100.

The second substrate 202 may be referred to as a substrate of the second semiconductor chip 200, the second front connection pad 212 may be referred to as a front connection pad of the second semiconductor chip 200, the second rear connection pad 214 may be referred to as a rear connection pad of the second semiconductor chip 200, the second interconnection layer 220 may be referred to as an interconnection layer of the second semiconductor chip 200, the second through-electrode 230 may be referred to as a through-electrode of the second semiconductor chip 200, the second front protective layer 242 may be referred to as a front protective layer of the second semiconductor chip 200, and the second rear protective layers 244 may be referred to as a rear protective layer of the second semiconductor chip 200.

In some embodiments, the first substrate 102 and the second substrate 202 may include Si (silicon). In some embodiments, the first substrate 102 and the second substrate 202 may include semiconductor devices, such as germanium (Ge) and compound semiconductors, such as, for example, silicon carbide (SiC), gallium arsenide (GaAs), indium arsenide (InAs), and indium phosphide (InP). The first substrate 102 and the second substrate 202 may have an active surface and an inactive surface disposed opposite to the active surface. The active surface and the inactive surface of the first substrate 102 may be referred to as a first active surface and a first inactive surface, respectively, and the active surface and the inactive surface of the second substrate 202 may be referred to as a second active surface and a second inactive surface, respectively. The second active surface of the second substrate 202 may face the first inactive surface of the first substrate 102.

The first substrate 102 and the second substrate 202 may include a plurality of various types of individual devices disposed on the active surface. The individual devices may include various microelectronics devices, for example, a metal-oxide-semiconductor field effect transistor (MOSFET), such as, for example, a complementary metal-insulator-semiconductor (CMOS) transistor, a system large scale integration (LSI), an image sensor, such as, for example, CMOS imaging sensor (CIS), a micro-electro-mechanical system (MEMS), an active device, a passive device, etc.

The first semiconductor chip 100 and the second semiconductor chip 200 may include a first semiconductor device 105 and a second semiconductor device 205 formed by the individual devices. The first semiconductor device 105 may be disposed on the first active surface of the first substrate 102, and the second semiconductor device 205 may be disposed on the second active surface of the second substrate 202.

In this specification, the front and rear surfaces of each of the first semiconductor chip 100 and the second semiconductor chip 200 refer to surfaces disposed adjacent to the active surface and the inactive surface of each of the first substrate 102 and the second substrate 202, and upper and lower surfaces of each of the first semiconductor chip 100 and the second semiconductor chip 200 refer to surfaces disposed on upper and lower sides in the drawings. For example, the front surface of each of the first semiconductor chip 100 and the second semiconductor chip 200 may be the lower surface of the first semiconductor chip 100 and the second semiconductor chip 200, and the rear surface of each of the first semiconductor chip 100 and the second semiconductor chip 200 may be the upper surface of each of the first semiconductor chip 100 and the second semiconductor chip 200.

The first semiconductor chip 100 and the second semiconductor chips 200 included in the semiconductor package 1 may be stacked sequentially in a face-down form with the first active surface and the second active surface facing downwardly. For example, the first active surface of the first substrate 102 included in the first semiconductor chip 100 may face the side opposite to the second semiconductor chips 200, and the first inactive surface may face the second semiconductor chips 200. The second active surface of the second substrate 202 included in each of the second semiconductor chips 200 may face the first semiconductor chip 100, and the second inactive surface may face the side opposite to the first semiconductor chip 100.

The first semiconductor chip 100 and the second semiconductor chips 200 may include, for example, dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM).

In some embodiments, the first semiconductor chip 100 do not include memory cells. The first semiconductor device 105 included in the first semiconductor chip 100 may include, for example, a serial-parallel conversion circuit, test logic circuits, such as, for example, design for test (DFT), Joint Test Action Group (JTAG), and memory built-in self-test (MBIST), and a signal interface circuit, such as, for example, PHY. The second semiconductor devices included in the second semiconductor chips 200 may include memory cells. For example, the first semiconductor chip 100 may be a buffer chip that controls the second semiconductor chips 200.

In some embodiments, the first semiconductor chip 100 may be a buffer chip that controls memory cells, and the second semiconductor chips 200 may be memory cell chips having memory cells controlled by the first semiconductor chip 100. The first semiconductor chip 100 may be referred to as, for example, a buffer chip, a master chip, or a main chip, and the second semiconductor chip 200 may be referred to as, for example, a memory cell chip, a slave chip, or a sub-chip. The first semiconductor chip 100 and the second semiconductor chips 200 stacked on the first semiconductor chip 100 may be collectively referred to as a DRAM device or a DRAM chip.

In some embodiments, the first semiconductor chip 100 may be a buffer chip that controls HBM DRAM, and the second semiconductor chips 200 may memory cell chips having a cell of the HBM DRAM controlled by the first semiconductor chip 100. The first semiconductor chip 100 and the second semiconductor chips 200 stacked on the first semiconductor chip 100 may be collectively referred to as an HBM DRAM device or an HBM DRAM chip.

The first interconnection layer 120 may be disposed on the first active surface of the first substrate 102. The first interconnection layer 120 may include a plurality of first interconnection patterns 122, a plurality of first interconnection vias 124, and a first inter-interconnection insulating layer 126. The first interconnection vias 124 may be connected to the upper and/or lower surfaces of the first interconnection patterns 122. In some embodiments, the first interconnection patterns 122 may be spaced apart from each other at different vertical levels, and the first interconnection vias 124 may connect the first interconnection patterns 122 arranged at different vertical levels to each other. The first interconnection patterns 122 and the first interconnection vias 124 may be electrically connected to the first semiconductor device 105 and the first through-electrodes 130. The first inter-interconnection insulating layer 126 may surround the first interconnection patterns 122 and the first interconnection vias 124.

The second interconnection layer 220 may be disposed on the second active surface of the second substrate 202. The second interconnection layer 220 may include a plurality of second interconnection patterns 222, a plurality of second interconnection vias 224, and a second inter-interconnection insulating layer 226. The second interconnection vias 224 may be connected to the upper and/or lower surfaces of the second interconnection patterns 222. In some embodiments, the second interconnection patterns 222 may be spaced apart from each other at different vertical levels, and the second interconnection vias 224 may connect the second interconnection patterns 222 disposed at different vertical levels to each other. The second interconnection patterns 222 and the second interconnection vias 224 may be electrically connected to the second semiconductor device 205 and the second through-electrodes 230. The second inter-interconnection insulating layer 226 may surround the second interconnection patterns 222 and the second interconnection vias 224.

The first interconnection patterns 122, the first interconnection vias 124, the second interconnection patterns 222, and the second interconnection vias 224 may include metals such as, for example, copper (Cu), aluminum (Al), tungsten (W), titanium (Ti), tantalum (Ta), molybdenum (Mo), cobalt (Co), nickel (Ni), alloys thereof, or nitrides of these metals. The first inter-interconnection insulating layer 126 and the second inter-interconnection insulating layer 226 may include, for example, high density plasma (HDP) oxide film, tetraethoxysilane (TEOS) oxide film, tonen silazene (TOSZ), spin on glass (SOG), undoped silica glass (USG), or a low-k dielectric layer.

The first front connection pads 112 may be disposed on the lower surface of the first substrate 102, and the first rear connection pads 114 may be disposed on the upper surface of the first substrate 102. For example, the first front connection pads 112 may be disposed on the lower surface of the first interconnection layer 120. The first front connection pads 112 may be electrically connected to the first interconnection patterns 122 and the first interconnection vias 124, and the first rear connection pads 114 may be electrically connected to the first through-electrodes 130. The second front connection pads 212 may be disposed on the lower surface of the second substrate 202, and the second rear connection pads 214 may be disposed on the upper surface of the second substrate 202. For example, the second front connection pads 212 may be disposed on the lower surface of the second interconnection layer 220. The second front connection pads 212 may be electrically connected to the second interconnection patterns 222 and the second interconnection vias 224, and the second rear connection pads 214 may be electrically connected to the second through-electrodes 230. In some embodiments, among the second semiconductor chips 200, the uppermost second semiconductor chip 200T disposed farthest from the first semiconductor chip 100 does not include the second rear connection pad 214.

The first through-electrodes 130 may electrically connect the first front connection pads 112 to the first rear connection pads 114 vertically through at least a portion of the first substrate 102. For example, the first front connection pad 112 and the first rear connection pad 114 corresponding to each other may be electrically connected through the first through-electrode 130, the first interconnection pattern 122, and the first interconnection via 124.

The second through-electrodes 230 may electrically connect the second front connection pads 212 to the second rear connection pads 214 vertically through at least a portion of the second substrate 202. For example, the second front connection pad 212 and the second rear connection pad 214 corresponding to each other may be electrically connected through the second through-electrode 230, the second interconnection pattern 222, and the second interconnection via 224. In some embodiments, among the second semiconductor chips 200, the uppermost second semiconductor chip 200T disposed farthest from the first semiconductor chip 100 does not include the second through-electrode 230.

Each of the first through-electrodes 130 and the second through-electrodes 230 may include a conductive plug and a conductive barrier film surrounding the conductive plug. The conductive plug may include Cu or W. For example, the conductive plug may include Cu, CuSn, CuMg, CuNi, CuZn, CuPd, CuAu, CuRe, CuW, W, or W alloy, but is not limited thereto. For example, the conductive plug may include one or more of Al, Au, Be, Bi, Co, Cu, Hf, In, Mn, Mo, Ni, Pb, Pd, Pt, Rh, Re, Ru, Ta, Te, Ti, W, Zn, and Zr, and may include one or two or more stack structures. The conductive barrier film may include at least one of, for example, W, WN, WC, Ti, TiN, Ta, TaN, Ru, Co, Mn, WN, Ni, or NiB and may include a single layer or multiple layers.

The first front protective layer 142 may cover the lower surface of the first interconnection layer 120. In some embodiments, the first front protective layer 142 does not cover, but exposes at least a portion of the lower surface of each of the first front connection pads 112. In some embodiments, the first front protective layer 142 may cover an edge portion of the lower surface of each of the first front connection pads 112 and does not cover, but exposes the central portion. The second front protective layer 242 may cover the lower surface of the second interconnection layer 220. In some embodiments, the second front protective layer 242 does not cover, but exposes at least a portion of the lower surface of each of the second front connection pads 212. In some embodiments, the second front protective layer 242 may cover an edge portion of the lower surface of each of the second front connection pads 212 and does not cover, but exposes the central portion. The first front protective layer 142 and the second front protective layer 242 may include nitride. In some embodiments, the first front protective layer 142 and the second front protective layer 242 may include silicon nitride.

The first rear protective layer 144 may cover the upper surface of the first substrate 102. In some embodiments, the first rear protective layer 144 does not cover, but exposes at least a portion of the upper surface of each of the first rear connection pads 114. In some embodiments, the first rear protective layer 144 may cover at least a portion of a side surface of each of the first rear connection pads 114. The second rear protective layer 244 may cover the upper surface of the second substrate 202. In some embodiments, the second rear protective layer 244 does not cover, but exposes at least a portion of the upper surface of each of the second rear connection pads 214. In some embodiments, the second rear protective layer 244 may cover at least a portion of a side surface of each of the second rear connection pads 214. The first rear protective layer 144 and the second rear protective layer 244 may include oxide or polymer. In some embodiments, the first rear protective layer 144 and the second rear protective layer 244 may include silicon oxide. For example, each of the first front protective layer 142 and the second front protective layer 242 may have a thickness of about 2 μm to about 4 μm. For example, each of the first rear protective layer 144 and the second rear protective layer 244 may have a thickness of about 2 μm to about 4 μm.

A plurality of first chip connection terminals 150 may be attached to the first front connection pads 112. The first chip connection terminals 150 may be disposed between the first semiconductor chip 100 and the package substrate 500 and electrically connect the first semiconductor chip 100 to the package substrate 500. The first chip connection terminals 150 may be disposed between the first front connection pads 112 and the package upper pads 522. A plurality of second chip connection terminals 250 may be attached to the second front connection pads 212. The second chip connection terminals 250 may be disposed between the first semiconductor chip 100 and the second semiconductor chips 200 and electrically connect the first semiconductor chip 100 to the second semiconductor chips 200. The second chip connection terminals 250 may be disposed between the second front connection pads 212 and the first rear connection pads 114 and between the second front connection pads 212 and the second rear connection pads 214. For example, the second chip connection terminals 250 may be disposed between the second front connection pads 212 included in the lowermost second semiconductor chip 200 among the second semiconductor chips 200 and the first rear connection pads 114 included in the first semiconductor chip 100 and between the second front connection pads 212 and the second rear connection pads 214 facing each other and included in two second semiconductor chips 200 disposed adjacent to each other among the second semiconductor chips 200.

The semiconductor package 1 further includes a plurality of first chip support structures 170 and a plurality of second chip support structures 270. The first chip support structures 170 may be disposed between the first semiconductor chip 100 and the package substrate 500. The first chip support structures 170 may be spaced apart from the first chip connection terminals 150 in a second direction (e.g., a horizontal direction) crossing the first direction, and may be disposed between the first semiconductor chip 100 and the package substrate 500. The second chip support structures 270 may be disposed between the first semiconductor chip 100 and the second semiconductor chips 200. The second chip support structures 270 may be spaced apart from the second chip connection terminals 250 in the horizontal direction and may be disposed between the second semiconductor chips 200. In some embodiments, the number of first chip support structures 170 disposed on the lower surface of the first semiconductor chip 100 may be equal to the number of second chip support structures 270 disposed on the lower surface of each of the second semiconductor chips 200, that is, on the lower surface of one second semiconductor chip 200. The first chip support structures 170 and the second chip support structures 270 may include metal. For example, the first chip support structures 170 and the second chip support structures 270 may include copper, nickel, stainless steel, or a copper alloy, such as beryllium copper.

The first chip connection terminal 150 may be referred to as a substrate connection terminal, the second chip connection terminal 250 may be referred to as a chip connection terminal, the first chip support structure 170 may be referred to as a substrate support structure, and the second chip support structure 270 may be referred to as a chip support structure. In some embodiments, the first chip connection terminal 150 may electrically connect the package substrate 500 to the first semiconductor chip 100, and the first chip support structure 170 does not electrically connect the package substrate 500 to the first semiconductor chip 100. In some embodiments, the second chip connection terminal 250 may electrically connect the first semiconductor chip 100 to the second semiconductor chips 200, and the second chip support structure 270 does not electrically connect the first semiconductor chip 100 to the second semiconductor chips 200.

The molding layer 900 may surround the first semiconductor chip 100 and the second semiconductor chips 200 on the package substrate 500. The molding layer 900 may include, for example, epoxy mold compound (EMC). In some embodiments, the molding layer 900 may fill a space between the package substrate 500 and the first semiconductor chip 100 and a space between the first semiconductor chip 100 and the second semiconductor chips 200. For example, the molding layer 900 may fill the space between the package substrate 500 and the first semiconductor chip 100 and surround the first chip connection terminals 150 and the first chip support structures 170, and may fill the space between the first semiconductor chip 100 and the second semiconductor chips 200 and surround the second chip connection terminals 250 and the second chip support structures 270.

In some embodiments, the molding layer 900 may cover the side surface, upper surface, and lower surface of each of the first semiconductor chip 100 and the second semiconductor chips 200, and does not cover the upper surface of the uppermost second semiconductor chip 200T among the second semiconductor chips 200. For example, the upper surface of the molding layer 900 may be substantially coplanar with the upper surface of the uppermost second semiconductor chip 200T. In some embodiments, the molding layer 900 may cover the upper surface of the uppermost second semiconductor chip 200T. For example, the upper surface of the molding layer 900 may be disposed at a vertical level higher than that of the upper surface of the uppermost second semiconductor chip 200T.

In some embodiments, the package substrate 500 may be an interposer. For example, the package substrate 500 may be a silicon interposer or a redistribution interposer. When the package substrate 500 is a silicon interposer, the package substrate 500 may include an interposer substrate, an interposer upper pad, an interposer lower pad, an interposer through-electrode, an interposer upper protective layer, and an interposer lower protective layer, instead of the package base insulating layer 510, the package upper pad 522, the package lower pad 524, the connection pattern 526, the upper solder resist layer 532, and the lower solder resist layer 534. The interposer substrate may include silicon (Si). The interposer through-electrode electrically connect the interposer upper pad to the interposer lower pad through the interposer substrate. The interposer upper protective layer and the interposer lower protective layer may include, for example, silicon oxide, silicon nitride, silicon oxynitride, or combinations thereof.

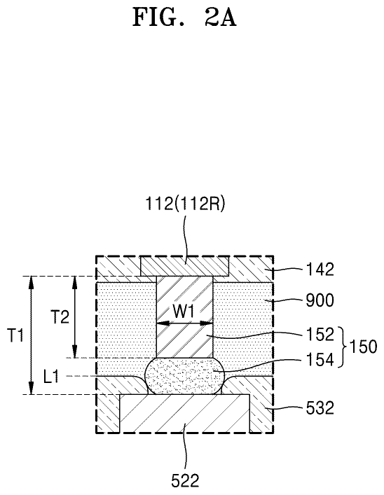

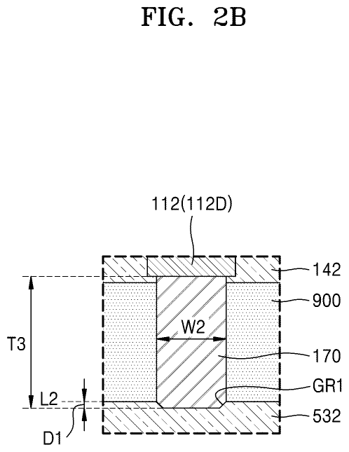

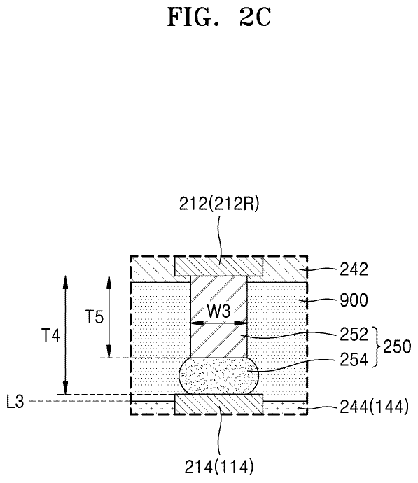

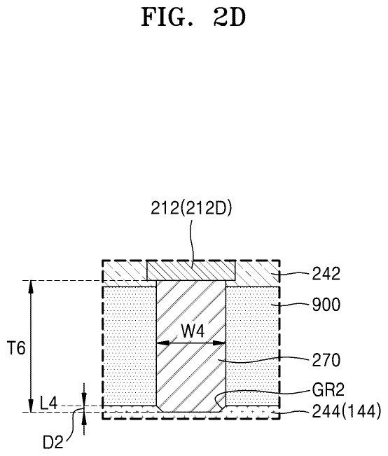

FIGS. 2A to 2D are enlarged cross-sectional views of the semiconductor package 1 according to embodiments. For example, FIGS. 2A to 2D are enlarged cross-sectional views illustrating portions A1, B1, C1, and D1 of FIG. 1. Although FIG. 2C shows the portion C1 of FIG. 1, that is, the second chip connection terminal 250 disposed between two adjacent second semiconductor chips 200 among the second semiconductor chips 200, the second chip connection terminal 250 disposed between the lowermost second semiconductor chip 200 among the second semiconductor chips 200 and the first semiconductor chip 100 may be substantially the same. Further, although FIG. 2D shows the portion D1 of FIG. 1, that is, the second chip support structure 270 disposed between two adjacent second semiconductor chips 200 among the second semiconductor chips 200, the second chip support structure 270 disposed between the lowermost second semiconductor chip 200 among the second semiconductor chips 200 and the first semiconductor chip 100 may be substantially the same.

Referring to FIG. 1 and FIGS. 2A to 2D, the first front connection pads 112 may include a first real front connection pad 112R and a first dummy front connection pad 112D, and the second front connection pads 212 may include a second real front connection pad 212R and a second dummy front connection pad 212D.

The first chip connection terminal 150 may be disposed between the first real front connection pad 112R and the package upper pad 522. The second chip connection terminal 250 may be disposed between the second real front connection pad 212R and the first rear connection pad 114 or between the second real front connection pad 212R and the second rear connection pads 214. For example, the second chip connection terminal 250 may be disposed between the second real front connection pad 212R included in the lowermost second semiconductor chip 200 among the second semiconductor chips 200 and the first rear connection pad 114 included in the first semiconductor chip 100, or may be disposed between the second real front connection pad 212R and the second rear connection pad 214 facing each other included in two second semiconductor chips 200 disposed adjacent to each other among the second semiconductor chips 200.

The first chip connection terminal 150 may include a first conductive pillar 152 attached to a lower surface of the first real front connection pad 112R and a first conductive cap 154 covering a lower surface of the first conductive pillar 152. The second chip connection terminal 250 may include a second conductive pillar 252 attached to a lower surface of the second real front connection pad 212R and a second conductive cap 254 covering a lower surface of the second conductive pillar 252. In some embodiments, a first under bump metal (UBM) layer may be disposed between the lower surface of the first real front connection pad 112R and the upper surface of the first conductive pillar 152, and a second UBM layer may be disposed between a lower surface of the second real front connection pad 212R and the upper surface of the second conductive pillar 252. The first conductive pillar 152 may be referred to as a substrate conductive pillar, the first conductive cap 154 may be referred to as a substrate conductive cap, the second conductive pillar 252 may be referred to as a chip conductive pillar, and the second conductive cap 254 may be referred to as a chip conductive cap.

The first conductive pillar 152 and the second conductive pillar 252 may include, for example, copper, nickel, stainless steel, or a copper alloy, such as beryllium copper. For example, the first conductive pillar 152 and the second conductive pillar 252 may be formed through a plating process, such as electrolytic plating or electroless plating. In some embodiments, the first conductive pillar 152 and the second conductive pillar 252 may include the same material as that of the first chip support structure 170 and the second chip support structure 270. For example, the first chip support structure 170 and the second chip support structure 270 may be formed by a plating process, such as, for example, electrolytic plating or electroless plating. In some embodiments, a plating process that forms the first conductive pillar 152 and the second conductive pillar 252 and a plating process that forms the first chip support structure 170 and the second chip support structure 270 may be performed separately. In some embodiments, upper portions of the first chip support structure 170 and the second chip support structure 270 may be formed together through the plating process to form the first conductive pillar 152 and the second conductive pillar 252, and lower portions of the first chip support structure 170 and the second chip support structure 270 may be formed through an additional plating process. The first conductive cap 154 and the second conductive cap 254 may include, for example, silver (Ag), tin (Sn), gold (Au), or solder. In some embodiments, the first conductive cap 154 and the second conductive cap 254 may include SnAg.

The first front connection pad 112 may be embedded in the first front protective layer 142. For example, the lowermost end of the first front protective layer 142 may be disposed at a vertical level lower than that of the lower surface of the first front connection pad 112. The first front protective layer 142 may cover a portion of the lower surface of the first front connection pad 112, for example, a portion of the lower surface adjacent to an edge, and the side surface. The second front connection pad 212 may be embedded in the second front protective layer 242. For example, the lowermost end of the second front protective layer 242 may be disposed at a vertical level lower than that of the lower surface of the second front connection pad 212. The second front protective layer 242 may cover a portion of the lower surface of the second front connection pad 212, for example, a portion of the lower surface adjacent to an edge, and the side surface.

An upper portion of the first conductive pillar 152 may extend into the first front protective layer 142 and may contact the first real front connection pad 112R. An upper portion of the second conductive pillar 252 may extend into the second front protective layer 242 and may contact the second real front connection pad 212R.

The package upper pad 522 may be embedded in the upper solder resist layer 532. For example, the uppermost end of the upper solder resist layer 532 may be disposed at a vertical level higher than that of the upper surface of the package upper pad 522. The upper solder resist layer 532 may cover a portion of the upper surface of the package upper pad 522, for example, a portion of the upper surface adjacent to an edge, and the side surface. A portion of the second rear connection pad 214 may protrude from the first rear protective layer 144 or the second rear protective layer 244. For example, the upper surface of the second rear connection pad 214 may be disposed at a vertical level higher than that of the uppermost end of the first rear protective layer 144 or the second rear protective layer 244. In some embodiments, each of the first rear protective layer 144 and the second rear protective layer 244 may cover a portion of the side surface of the second rear connection pad 214, for example, a lower portion of the side surface, but does not cover the upper surface.

In some embodiments, the lower portion of the first conductive cap 154 may extend into the upper solder resist layer 532 and contact the package upper pad 522. In some embodiments, the second conductive cap 254 does not extend into the first rear protective layer 144 or the second rear protective layer 244, but may contact the second rear connection pad 214.

An upper portion of the first chip support structure 170 may extend into the first front protective layer 142, and a lower portion of the first chip support structure 170 may extend into the upper solder resist layer 532. In some embodiments, the first chip support structure 170 does not penetrate through the first front protective layer 142 and the upper solder resist layer 532. The upper portion of the first chip support structure 170 may extend into the first front protective layer 142, so that the upper surface of the first chip support structure 170 may contact the first dummy front connection pad 112D, and the lower portion of the first chip support structure 170 may extend into the upper solder resist layer 532 so that the lower surface of the first chip support structure 170 may contact the upper solder resist layer 532. For example, the upper solder resist layer 532 may have a first groove GR1 extending inwardly from the upper surface, and a lower portion of the first chip support structure 170 may fill the first groove GR1.

The upper portion of the second chip support structure 270 may extend into the second front protective layer 242 and the lower portion of the second chip support structure 270 may extend into the first rear protective layer 144 or the second rear protective layer 244. In some embodiments, the second chip support structure 270 does not penetrate through the first front protective layer 142, the first rear protective layer 144, and the second rear protective layer 244. The upper portion of the second chip support structure 270 may extend into the second front protective layer 242, so that the upper surface of the second chip support structure 270 may contact the second dummy front connection pad 212D, and the lower portion of the second chip support structure 270 may extend into the first rear protective layer 144 or the second rear protective layer 244, so that the lower surface of the second chip support structure 270 may contact the first rear protective layer 144 or the second rear protective layer 244. For example, each of the first rear protective layer 144 and the second rear protective layer 244 may have a second groove GR2 extending inwardly from the upper surface, and the lower portion of the second chip support structure 270 may fill the second groove GR2.

The lower portion of the first chip support structure 170 may extend from top to bottom and may have a tapered shape with a decreasing horizontal width. The first groove GR1 may have a tapered shape extending from top to bottom and having a decreasing horizontal width, corresponding to the lower portion of the first chip support structure 170 having a tapered shape. The lower portion of the second chip support structure 270 may have a tapered shape extending from top to bottom and having a decreasing horizontal width. The second groove GR2 may have a tapered shape extending from top to bottom and having a decreasing horizontal width, corresponding to the lower portion of the second chip support structure 270 having a tapered shape.

The first chip connection terminal 150 may have a first thickness T1, the first conductive pillar 152 may have a second thickness T2, and the first chip support structure 170 may have a third thickness T3. The third thickness T3 may have a value greater than the second thickness T2. In some embodiments, the third thickness T3 may have a value greater than the first thickness T1. The third thickness T3 may have a value greater than a gap between the upper solder resist layer 532 and the first front protective layer 142. For example, the first thickness T1 may be between about 15 μm and about 30 μm, the second thickness T2 may be less than the first thickness T1 and may be between about 10 μm and about 20 μm, and the third thickness T3 may have a value that is about 0.5 μm to about 3 μm greater than the first thickness T1. The first thickness T1, the second thickness T2, and the third thickness T3 may be referred to as a first height, a second height, and a third height, respectively. The first conductive pillar 152 may have a first horizontal width W1, and the first chip support structure 170 may have a second horizontal width W2. In some embodiments, the second horizontal width W2 may have a value greater than the first horizontal width W1. For example, the first horizontal width W1 may be between about 15 μm and about 40 μm, and the second horizontal width W2 may be about 5% to about 20% greater than the first horizontal width W1. The uppermost end of the upper solder resist layer 532 may be disposed on the package upper pad 522 and may be disposed at a first vertical level L1. A portion of the upper surface of the upper solder resist layer 532 in contact with the first chip support structure 170 may be disposed at a second vertical level L2 that is lower than the first vertical level L1.

The second chip connection terminal 250 may have a fourth thickness T4, the second conductive pillar 252 may have a fifth thickness T5, and the second chip support structure 270 may have a sixth thickness T6. The sixth thickness T6 may have a value greater than the fifth thickness T5. In some embodiments, the sixth thickness T6 may have a value greater than the fourth thickness T4. In some embodiments, the fourth thickness T4 may have about the same value as the first thickness T1, the fifth thickness T5 may have about the same value as the second thickness T2, and the sixth thickness T6 may have about the same value as the third thickness T3. The sixth thickness T6 may have a value greater than an interval between the first rear protective layer 144 and the second front protective layer 242 facing each other and an interval between the second rear protective layer 244 and the second front protective layer 242 facing each other. For example, the fourth thickness T4 may be between about 15 μm and about 30 μm, the fifth thickness T5 may be less than the fourth thickness T4 and between about 10 μm and about 20 μm, and the sixth thickness T6 may have a value that is about 0.5 μm to about 3 μm greater than the fourth thickness T4. The fourth thickness T4, the fifth thickness T5, and the sixth thickness T6 may be referred to as a fourth height, a fifth height, and a sixth height, respectively. The second conductive pillar 252 may have a third horizontal width W3, and the second chip support structure 270 may have a fourth horizontal width W4. In some embodiments, the fourth horizontal width W4 may have a value greater than the third horizontal width W3. In some embodiments, the first horizontal width W1 may have about the same value as the third horizontal width W3, and the second horizontal width W2 may have about the same value as the fourth horizontal width W4. For example, the third horizontal width W3 may be between about 15 μm and about 40 μm, and the fourth horizontal width W4 may have a value that is about 5% to about 20% greater than the third horizontal width W3. A portion of the upper surface of the first rear protective layer 144 that is in contact with the first rear connection pad 114 or a portion of the upper surface of the second rear protective layer 244 that is in contact with the second rear connection pad 214 may be disposed at the third vertical level L3, and a portion of the upper surface of the first rear protective layer 144 that is in contact with a second chip support structure 280 or a portion of the upper surface of the second rear protective layer 244 that is in contact with the second chip support structure 280 may be disposed at a fourth vertical level LA. In some embodiments, the third vertical level L3 may be substantially the same as the fourth vertical level LA.

The first groove GR1 may have a first depth D1 from the upper surface of the upper solder resist layer 532, that is, the second vertical level L2, and the second groove GR2 may have a second depth D2 from the upper surface of each of the first rear protective layer 144 and the second rear protective layer 244, that is, the fourth vertical level L4. In some embodiments, the first depth D1 may have about the same value as the second depth D2. In some embodiments, a vertical level difference between the first vertical level L1 and the upper surface of the package upper pad 522 may have a value less than the first depth D1. For example, the first depth D1 and the second depth D2 may each be between about 0.5 μm and about 2 μm.

Since the semiconductor package 1 according to embodiments of the inventive concept includes the first chip support structures 170 and the second chip support structures 270, in the process of attaching the first semiconductor chip 100 and the second semiconductor chips 200 to the package substrate 500 and forming the molding layer 900 surrounding the first semiconductor chip 100 and the second semiconductor chips 200, a lower jig may be disposed below the package substrate 500 and an upper jig may be disposed above the uppermost second semiconductor chip 200T, and pressure may then be applied between the lower jig and the upper jig. As a result, warpage may be prevented from occurring in the package substrate 500, the first semiconductor chip 100, and the second semiconductor chips 200 included in the semiconductor package 1, which may increase structural reliability and the reliability of the electrical connection between the package substrate 500, the first semiconductor chip 100, and the second semiconductor chips 200.

In addition, in the semiconductor package 1 according to embodiments of the inventive concept, because the first chip support structures 170 and the second chip support structures 270 are coupled to the first groove GR1 and the second groove GR2, misalignment between the package substrate 500, the first semiconductor chip 100, and the second semiconductor chips 200 may be prevented.

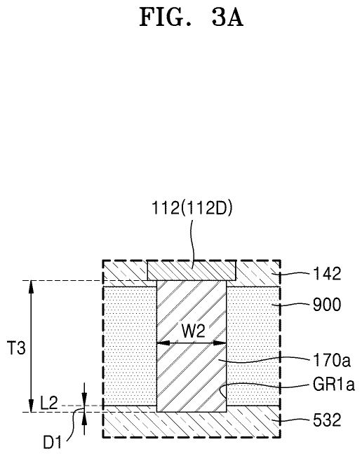

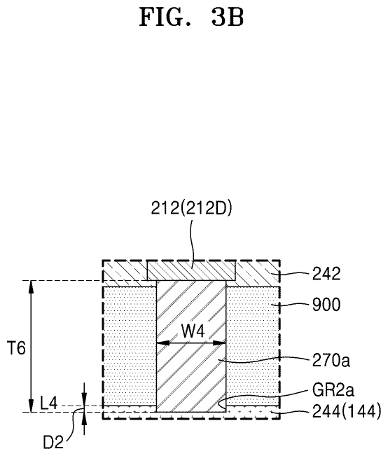

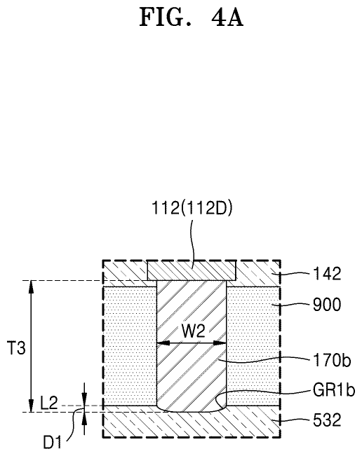

FIGS. 3A and 3B are enlarged cross-sectional views of the semiconductor package 1 according to an embodiment. For example, FIGS. 3A and 3B are enlarged cross-sectional views illustrating the portions B1 and D1 of FIG. 1.

Referring to FIG. 1 and FIGS. 3A and 3B, the semiconductor package 1 includes a plurality of first chip support structures 170a and a plurality of second chip support structures 270a, instead of the first chip support structures 170 and the second chip support structures 270.

The upper solder resist layer 532 may have a first groove GR1a extending inwardly from the upper surface, and a lower portion of the first chip support structure 170a may fill the first groove GR1a. Each of the first rear protective layer 144 and the second rear protective layer 244 may have a second groove GR2a extending inwardly from the upper surface, and a lower portion of the second chip support structure 270a may fill the second groove GR2a.

The first chip support structure 170a may extend from top to bottom and may have substantially the same horizontal width. The first groove GR1a may extend from top to bottom and may have a substantially equal horizontal width, corresponding to the first chip support structure 170a having substantially the same horizontal width. A lower portion of the second chip support structure 270a may extend from top to bottom and may have substantially the same horizontal width. The second groove GR2a may extend from top to bottom and may have a substantially equal horizontal width, corresponding to the second chip support structure 270a having substantially the same horizontal width.

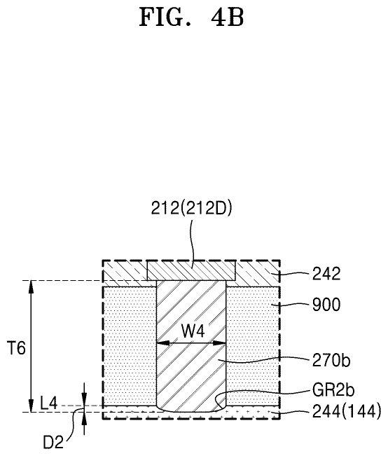

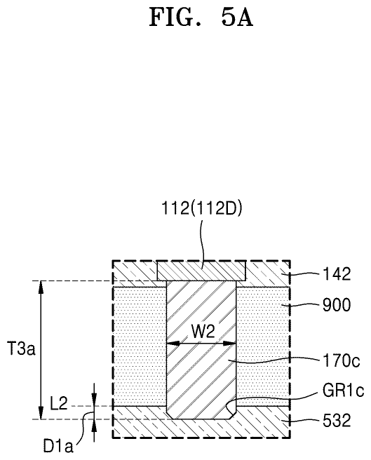

FIGS. 4A and 4B are enlarged cross-sectional views of the semiconductor package 1 according to an embodiment. For example, FIGS. 4A and 4B are enlarged cross-sectional views illustrating the portions B1 and D1 of FIG. 1.

Referring to FIG. 1 and FIGS. 4A and 4B, the semiconductor package 1 includes a plurality of first chip support structures 170b and a plurality of second chip support structures 270b, instead of the first chip support structures 170 and the second chip support structures 270.

The upper solder resist layer 532 may have a first groove GR1b extending inwardly from the upper surface, and the lower portion of the first chip support structure 170b may fill the first groove GR1b. Each of the first rear protective layer 144 and the second rear protective layer 244 may have a second groove GR2b extending inwardly from the upper surface, and the lower portion of the second chip support structure 270b may fill the second groove GR2b.

The lower portion of the first chip support structure 170b may be convex downwardly. The first groove GR1b may be concave inwardly from the upper surface of the upper solder resist layer 532, corresponding to the lower portion of the first chip support structure 170b having a convex shape. The lower portion of the second chip support structure 270b may be convex downwardly. The second groove GR2b may be concave inwardly from the upper surface of each of the first and second rear protective layers 144 and 244, corresponding to the lower portion of the second chip support structure 270b having a convex shape.

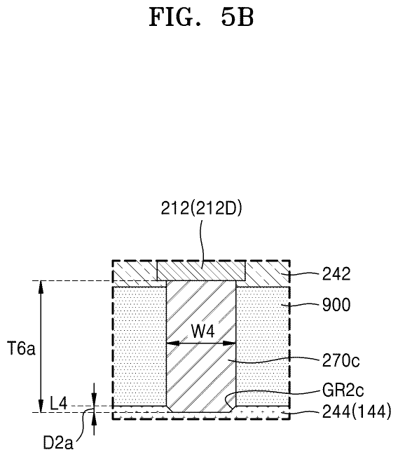

FIGS. 5A and 5B are enlarged cross-sectional views of the semiconductor package 1 according to an embodiment. For example, FIGS. 5A and 5B are enlarged cross-sectional views illustrating the portions B1 and D1 of FIG. 1.

Referring to FIG. 1 and FIGS. 5A and 5B, the semiconductor package 1 includes a plurality of first chip support structures 170c and a plurality of second chip support structures 270c, instead of the first chip support structures 170 and the second chip support structures 270.

The upper solder resist layer 532 may have a first groove GR1c extending inwardly from the upper surface, and a lower portion of the first chip support structure 170c may fill the first groove GR1c. Each of the first rear protective layer 144 and the second rear protective layer 244 may have a second groove GR2c extending inwardly from the upper surface, and a lower portion of the second chip support structure 270c may fill the second groove GR2c.

The first chip support structure 170c may have a third thickness T3a, and the second chip support structure 270c may have a sixth thickness T6a. The first groove GR1c may have a first depth D1a from the upper surface of the upper solder resist layer 532, that is, the second vertical level L2, and the second groove GR2c may have a second depth D2a from the upper surface of each of the first rear protective layer 144 and the second rear protective layer 244, that is, the fourth vertical level LA. In some embodiments, the first depth D1a may have a value greater than the second depth D2a, and the sixth thickness Toa may have a value greater than the third thickness T3a. For example, the first depth D1a may have a value of about 0.5 μm to about 5 μm greater than the second depth D2a, and the sixth thickness Toa may have a value of about 0.5 μm to about 5 μm greater than the third thickness T3a.

Although it is illustrated in FIGS. 5A and 5B that the lower portion of each of the first chip support structure 170c and the second chip support structure 270c has a tapered shape extending from top to bottom and a decreasing horizontal width and each of the first groove GR1c and the second groove GR2c has a corresponding shape, the inventive concept is not limited thereto. For example, in some embodiments, each of the first chip support structure 170c and the second chip support structure 270c may extend from top to bottom and have substantially the same horizontal width, and each of the first groove GR1c and the second groove GR2c may have a corresponding shape, similar to each of the first chip support structure 170a and the second chip support structure 270a shown in FIGS. 3A and 3B. In some embodiments, for example, the lower portion of each of the first chip support structure 170c and the second chip support structure 270c may be convex downwardly and each of the first groove GR1c and the second groove GR2c may have a corresponding shape, similar to the first chip support structure 170b and the second chip support structure 270b shown in FIGS. 4A and 4B.

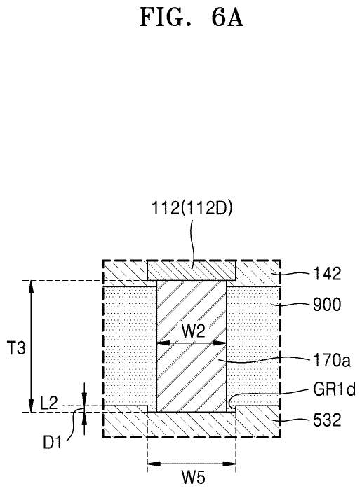

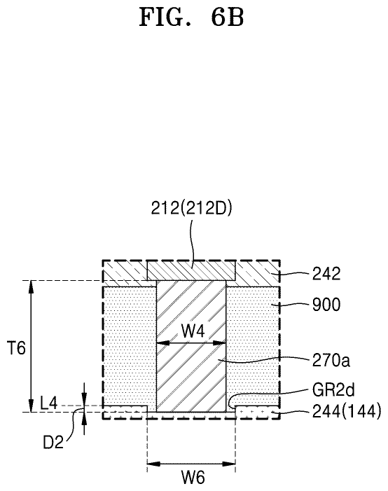

FIGS. 6A and 6B are enlarged cross-sectional views of the semiconductor package 1 according to an embodiment. For example, FIGS. 6A and 6B are enlarged cross-sectional views illustrating the portions B1 and D1 of FIG. 1.

Referring to FIG. 1 and FIGS. 6A and 6B, the semiconductor package 1 includes a plurality of first chip support structures 170a and a plurality of second chip support structures 270a, instead of the first chip support structures 170 and the second chip support structures 270.

The upper solder resist layer 532 may have a first groove GR1d extending inwardly from the upper surface, and a lower portion of the first chip support structure 170a may fill a portion of the first groove GR1d. Each of the first rear protective layer 144 and the second rear protective layer 244 may have a second groove GR2d extending inwardly from the upper surface, and a lower portion of the second chip support structure 270a may fill a portion of the second groove GR2d.

The first chip support structure 170a may have a second width W2, and the first groove GR1d may have a fifth width W5 that is greater than the second width W2. For example, the fifth width W5 may have a value that is about 0.5 μm to about 2 μm greater than the second width W2. The second chip support structure 270a may have a fourth width W4, and the second groove GR2d may have a sixth width W6 that is greater than the fourth width W4. For example, the sixth width W6 may have a value that is about 0.5 μm to about 2 μm greater than the fourth width W4.

Although it is illustrated in FIGS. 6A and 6B that the first chip support structure 170a and the second chip support structure 270a each extend from top to bottom and have substantially the same horizontal width, and the first groove GR1d and the second groove GR2d each correspond thereto and have a large horizontal width, the inventive concept is not limited thereto. For example, in some embodiments, the lower portion of each of the first chip support structure 170a and the second chip support structure 270a may extend from top to bottom and have a tapered shape with a decreasing horizontal width and each of the first groove GR1d and the second groove GR2d may correspond thereto and have a shape with a large horizontal width, similar to each of the first chip support structure 170 and the second chip support structure 270 shown in FIGS. 2A and 2B. In some embodiments, for example, the lower portion of each of the first chip support structure 170a and the second chip support structure 270a may be convex downwardly and each of the first groove GR1d and the second groove GR2d may correspond thereto and have a large horizontal width, similar to each of the first chip support structure 170b and the second chip support structure 270b shown in FIGS. 4A and 4B.

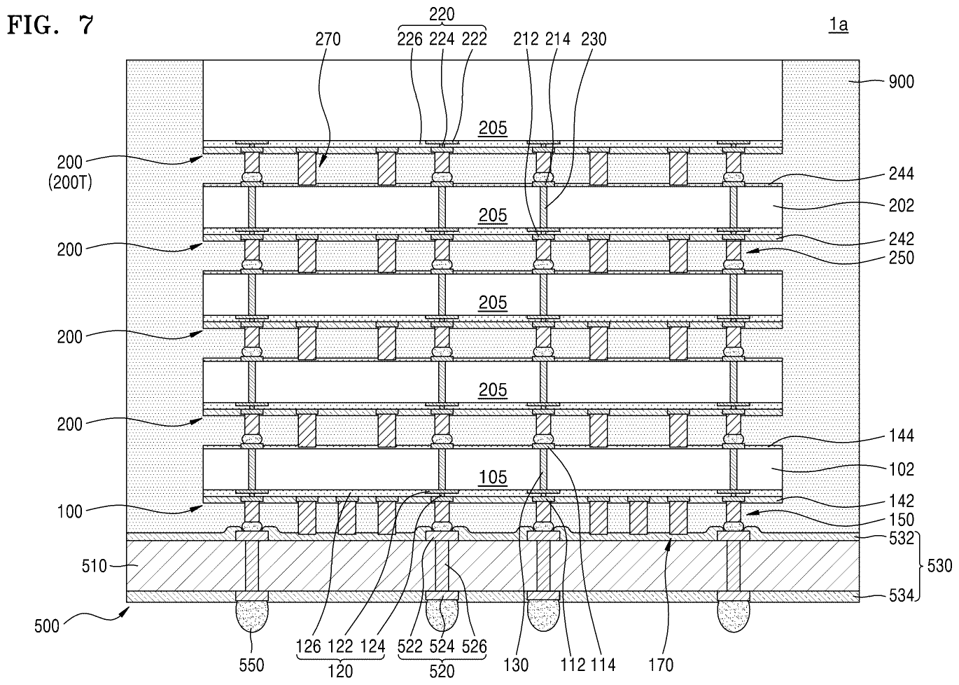

FIG. 7 is a cross-sectional view of a semiconductor package 1a according to an embodiment.

Referring to FIG. 7, the semiconductor package 1a may include the package substrate 500, the first semiconductor chip 100 attached to the package substrate 500, the second semiconductor chips 200 stacked on the first semiconductor chip 100, and the molding layer 900 surrounding the first semiconductor chip 100 and the second semiconductor chips 200 on the package substrate 500.

The semiconductor package 1a further includes the first chip support structures 170 and the second chip support structures 270. In some embodiments, the number of first chip support structures 170 disposed on the lower surface of the first semiconductor chip 100 may be greater than the number of second chip support structures 270 disposed on the lower surface of each of the second semiconductor chips 200, that is, the lower surface of one second semiconductor chip 200.

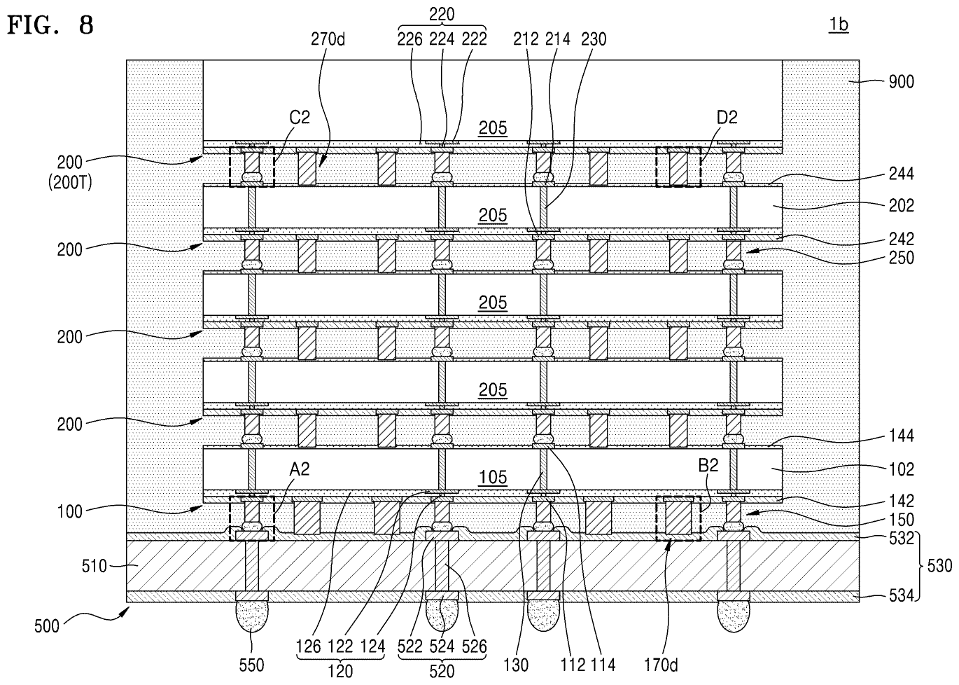

FIG. 8 is a cross-sectional view of a semiconductor package 1b according to an embodiment.

Referring to FIG. 8, the semiconductor package 1b may include the package substrate 500, the first semiconductor chip 100 attached to the package substrate 500, the second semiconductor chips 200 stacked on the first semiconductor chip 100, and the molding layer 900 surrounding the first semiconductor chip 100 and the second semiconductor chips 200 on the package substrate 500.

The semiconductor package 1b further includes a plurality of first chip support structures 170d and a plurality of second chip support structures 270d. In some embodiments, the number of first chip support structures 170d disposed on the lower surface of the first semiconductor chip 100 may be about equal to the number of second chip support structures 270d disposed on the lower surface of each of the second semiconductor chips 200, that is, one second semiconductor chip 200.

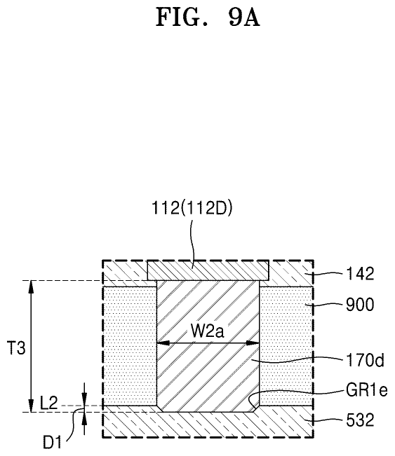

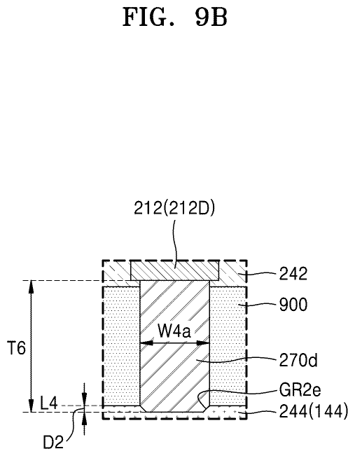

FIGS. 9A and 9B are enlarged cross-sectional views of the semiconductor package 1b according to an embodiment. For example, FIGS. 9A and 9B are enlarged cross-sectional views illustrating portions B2 and D2 of FIG. 8.

Referring to FIGS. 8, 9A, and 9B, the first chip support structure 170d may have a second horizontal width W2a, and the second chip support structure 270d may have a fourth horizontal width W4a. In some embodiments, the second horizontal width W2a may have a value greater than the fourth horizontal width W4a. For example, the fourth horizontal width W4a may have a value that is about 5% to about 20% greater than the first horizontal width W1 shown in FIG. 2A, and the second horizontal width W2a may have a value that is about 5% to about 20% greater than the fourth horizontal width W4a.

The upper solder resist layer 532 may have a first groove GR1e extending inwardly from the upper surface, and a lower portion of the first chip support structure 170d may fill a portion of the first groove GR1e. Each of the first rear protective layer 144 and the second rear protective layer 244 may have a second groove GR2e extending inwardly from the upper surface, and a lower portion of the second chip support structure 270d may fill a portion of the second groove GR2e.

Enlarged cross-sectional views of portions A2 and C2 of FIG. 8 may correspond to FIGS. 2A and 2C. In addition, in some embodiments, the shape of each of the first chip support structure 170d, the second chip support structure 270d, the first groove GR1e, and the second groove GR2e may be modified with reference to FIGS. 3A to 6B.

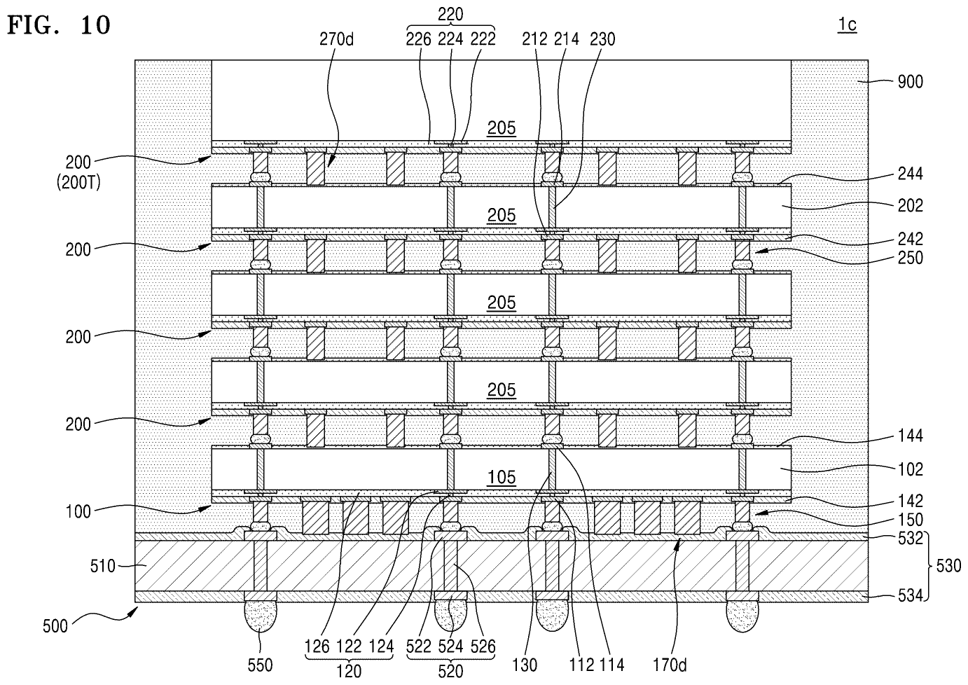

FIG. 10 is a cross-sectional view of a semiconductor package 1c according to an embodiment.

Referring to FIG. 10, the semiconductor package 1c may include the package substrate 500, the first semiconductor chip 100 attached to the package substrate 500, the second semiconductor chips 200 stacked on the first semiconductor chip 100, and the molding layer 900 surrounding the first semiconductor chip 100 and the second semiconductor chips 200 on the package substrate 500.

The semiconductor package 1c further includes the first chip support structures 170d and the second chip support structures 270d. In some embodiments, the number of first chip support structures 170d disposed on the lower surface of the first semiconductor chip 100 may be greater than the number of second chip support structures 270d disposed on the lower surface of each of the second semiconductor chips 200, that is, the lower surface of one second semiconductor chip 200.

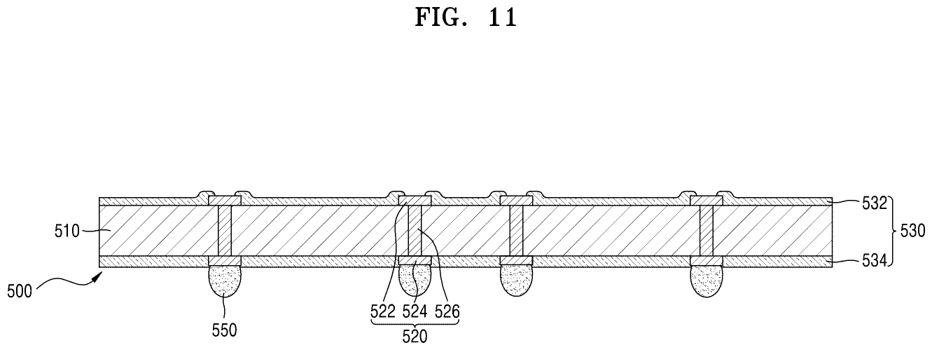

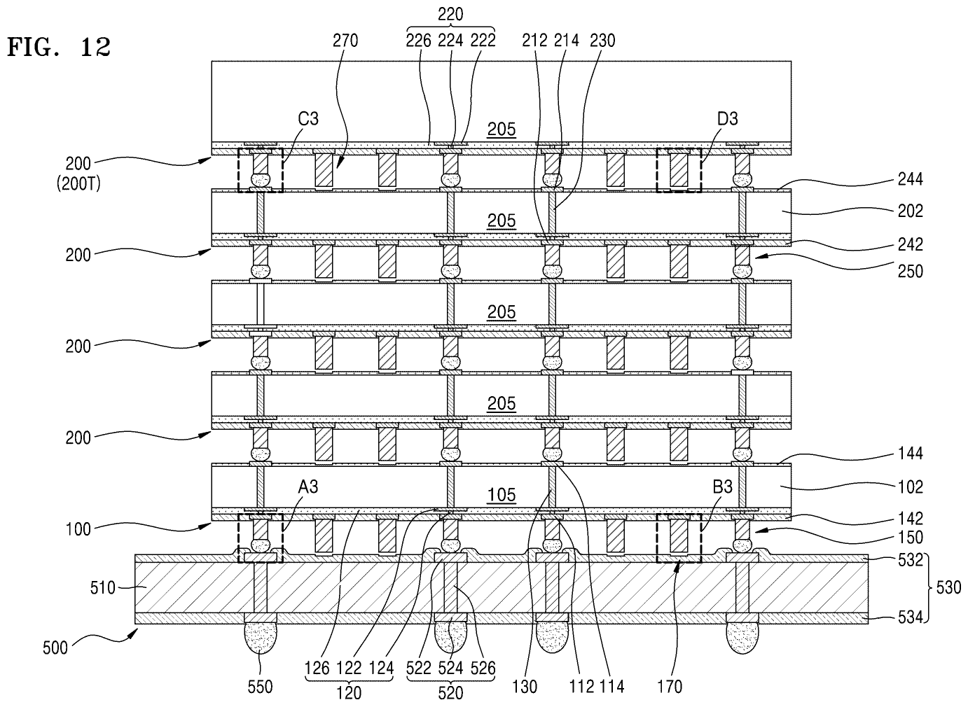

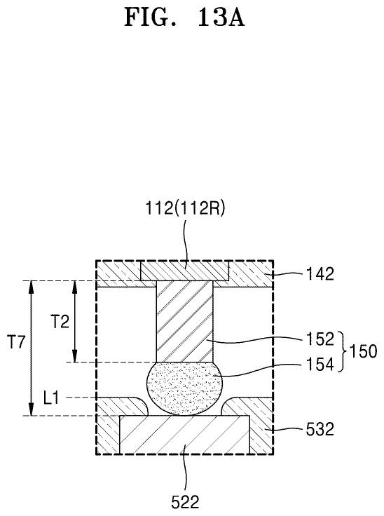

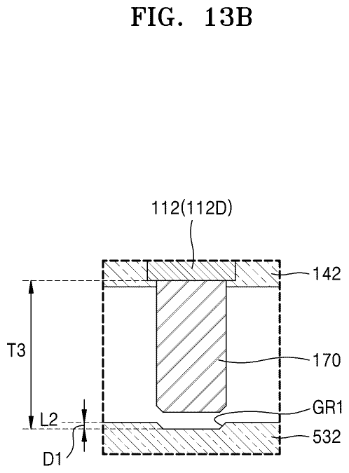

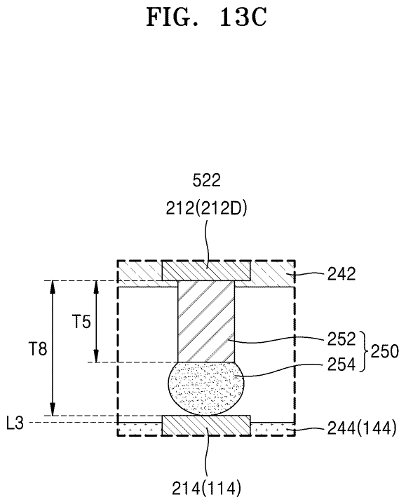

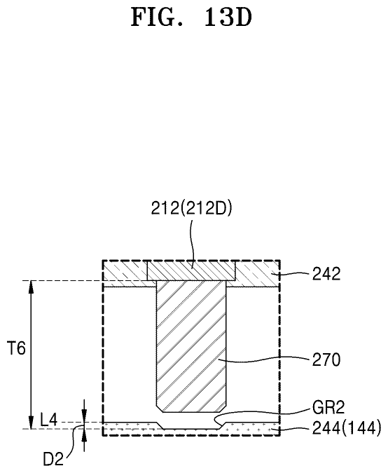

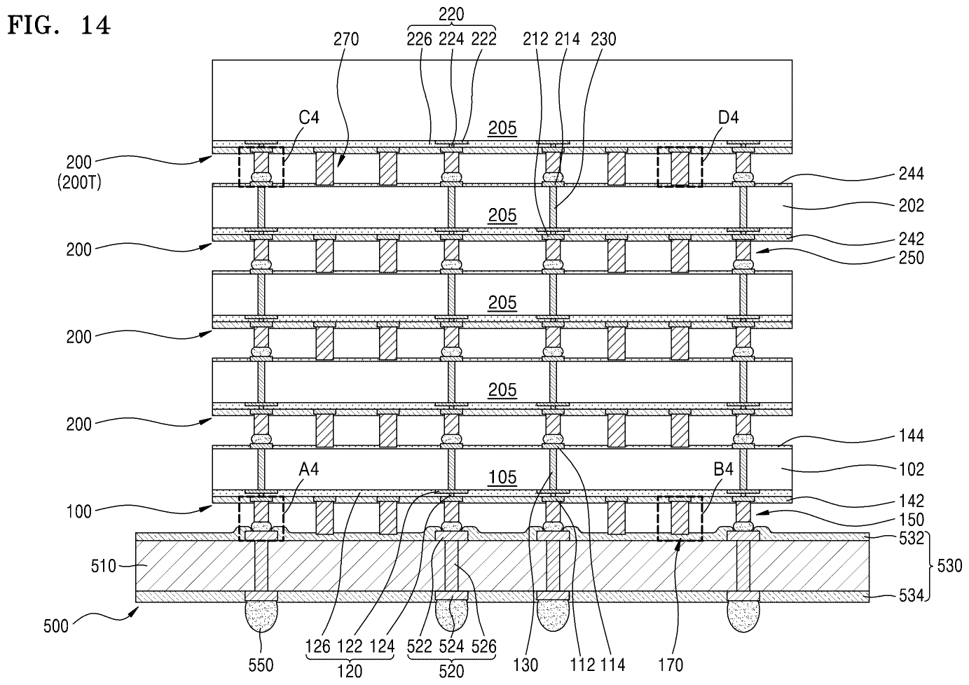

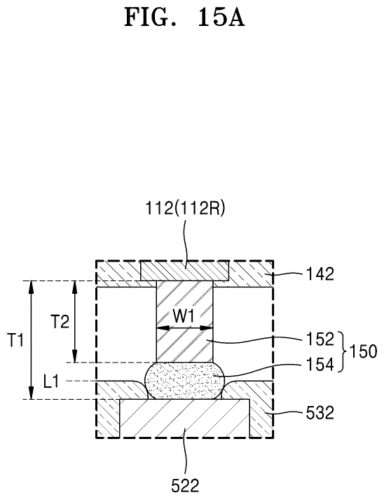

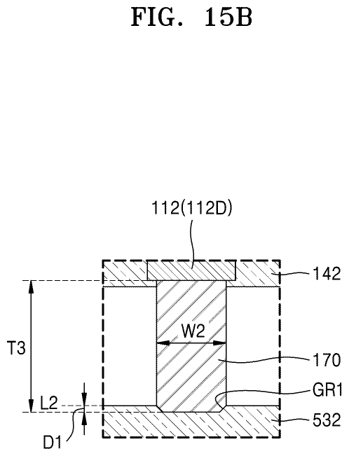

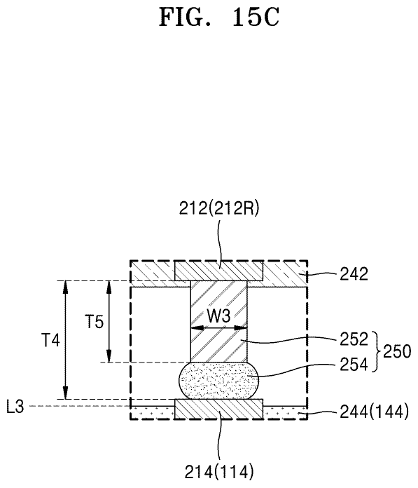

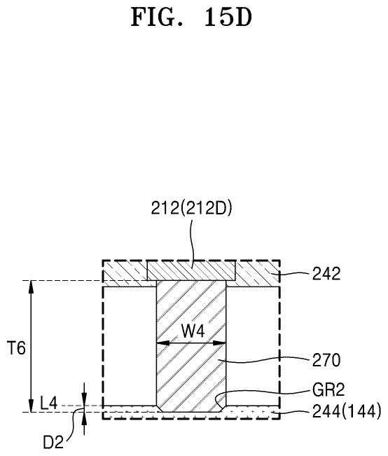

FIGS. 11, 12, 13A-13D, 14 and 15A to 15D are cross-sectional views and enlarged cross-sectional views illustrating a method of manufacturing a semiconductor package according to embodiments. For example, FIGS. 13A to 13D are enlarged cross-sectional views illustrating portions A3, B3, C3, and D3 of FIG. 12, and FIGS. 15A to 15D are enlarged cross-sectional views illustrating portions A4, B4, C4, and D4 of FIG. 14.

Referring to FIG. 11, the package substrate 500 is prepared. The package substrate 500 may include the package base insulating layer 510, the package conductive patterns 520, and the solder resist layer 530. The package conductive patterns 520 may include the package upper pads 522, the package lower pads 524, and the connection patterns 526. The package upper pads 522 may be disposed on the upper surface of the package base insulating layer 510, and the package lower pads 524 may be disposed on a lower surface of the package base insulating layer 510. The connection patterns 526 may electrically connect the package upper pads 522 to the package lower pads 524.

In FIG. 11, the package connection terminals 550 are shown attached to the package lower pads 524 on the lower surface of the package substrate 500. However, this is an example provided for convenience of illustration, and the inventive concept is not limited thereto. For example, in some embodiments, the package connection terminals 550 may be attached to the package lower pads 524 in a subsequent operation. For example, the package connection terminals 550 may be attached to the package lower pads 524 after the molding layer 900 shown in FIG. 1 is formed.

Referring to FIG. 12, the first semiconductor chip 100 and the second semiconductor chips 200 are sequentially disposed on the package substrate 500. The first semiconductor chip 100 may be disposed on the package substrate 500 so that the first chip connection terminals 150 correspond to the package upper pads 522 of the package substrate 500. Among the second semiconductor chips 200, the lowermost second semiconductor chip 200 may be disposed on the first semiconductor chip 100 so that the second chip connection terminals 250 correspond to the first rear connection pads 114 of the first semiconductor chip 100, and the other second semiconductor chips 200 may be disposed on the second semiconductor chip 200 therebelow so that the second chip connection terminals 250 correspond to the second rear connection pads 214 of the second semiconductor chip 200 therebelow.

In some embodiments, the first chip connection terminals 150 may be in contact with the package upper pads 522, but the first chip support structures 170 are not in contact with the upper solder resist layer 532, and the second chip connection terminals 250 may be in contact with the first rear connection pads 114 or the second rear connection pads 214, but the second chip support structures 270 are not in contact with the first rear protective layer 144 or the second rear protective layer 244.

Referring to FIG. 12 and FIGS. 13A to 13D, the first semiconductor chip 100 may be disposed on the package substrate 500 so that the first chip connection terminals 150 are in contact with the package upper pads 522. For example, the first conductive cap 154 of the first chip connection terminal 150 may contact the package upper pad 522. The first chip connection terminal 150 may have a seventh thickness T7. The seventh thickness T7 may have a value greater than the first thickness T1 shown in FIG. 2A. The seventh thickness T7 may be referred to as a seventh height.

In some embodiments, the first chip support structures 170 does not contact, but is apart from the upper solder resist layer 532. In some embodiments, a vertical level of the lower end of the first chip support structure 170 may be higher than the second vertical level L2 so that the first chip support structure 170 does not fill the first groove GR1, but the inventive concept is not limited thereto. For example, in some embodiments, the first chip support structure 170 is not in contact with the upper solder resist layer 532, but may extend into the first groove GR1 so that a lower portion of the first chip support structure 170 may be disposed within the first groove GR1.

The lowermost second semiconductor chip 200 among the second semiconductor chips 200 may be disposed on the first semiconductor chip 100 so that the second chip connection terminals 250 are in contact with the first rear connection pads 114, and the other second semiconductor chips 200 among the second semiconductor chips 200 may be disposed on the second semiconductor chip 200 therebelow so that the second chip connection terminals 250 are in contact with the second rear connection pads 214. For example, the second conductive cap 254 of the second chip connection terminal 250 may be in contact with the first rear connection pad 114 or the second rear connection pad 214. The second chip connection terminal 250 may have an eighth thickness T8. The eighth thickness T8 may have a value greater than the fourth thickness T4 shown in FIG. 2C. The eighth thickness T8 may be referred to as an eighth height.

In some embodiments, the second chip support structures 270 do not contact, but are apart from the first rear protective layer 144 or the second rear protective layer 244. In some embodiments, a vertical level of the lower end of the second chip support structure 270 may be higher than the fourth vertical level L4 so that the second chip support structure 270 does not fill the second groove GR2, but the inventive concept is not limited thereto. For example, in some embodiments, the second chip support structure 270 does not contact the first rear protective layer 144 or the second rear protective layer 244, but extends into the second groove GR2 so that a lower portion of the second rear protective layer 244 may be disposed within the second groove GR2.

Referring to FIG. 14, a reflow process may be performed to attach the first chip connection terminals 150 to the package upper pads 522 and the second chip connection terminals 250 to the first rear connection pads 114 and the second rear connection pads 214.

Referring to FIG. 14 and FIGS. 15A to 15D, through the reflow process, the first conductive cap 154 of the first chip connection terminal 150 may be coupled to the package upper pad 522 and the second conductive cap 254 of the second chip connection terminal 250 may be coupled to the first rear connection pad 114 or the second rear connection pad 214. Through the reflow process, the thickness of each of the first conductive cap 154 of the first chip connection terminal 150 and the second conductive cap 254 of the second chip connection terminal 250 may be reduced, so that the first chip connection terminal 150 may have the first thickness T1 and the second chip connection terminal may have the fourth thickness T4. The first thickness T1 may have a value less than the seventh thickness T7 shown in FIG. 13A, and the fourth thickness T4 may have a value less than the eighth thickness T8 shown in FIG. 13C.

As the thickness of the first chip connection terminal 150 decreases through the reflow process, the first chip support structure 170 may extend into the first groove GR1 so that the lower portion may fill the first groove GR1 and contact the upper solder resist layer 532, and as the thickness of the second chip connection terminal 250 decreases through the reflow process, the second chip support structure 270 may extend into the second groove GR2 so that the lower portion may fill the second groove GR2 and contact the first rear protective layer 144 or the second rear protective layer 244.

Thereafter, the semiconductor package 1 may be formed by forming the molding layer 900 surrounding the first semiconductor chip 100 and the second semiconductor chips 200 on the package substrate 500 shown in FIG. 1.

Referring to FIGS. 1 to 15D, in the semiconductor package 1 according to embodiments of the inventive concept, in the process of performing the reflow process and forming the molding layer 900, the first chip support structures 170 may be coupled to the first grooves GR1 and the second chip support structures 270 may be coupled to the second grooves GR2, which may prevent misalignment among the package substrate 500, the first semiconductor chip 100, and the second semiconductor chips 200. In addition, because the intervals among the package substrate 500, the first semiconductor chip 100, and the second semiconductor chips 200 are maintained by the first chip support structures 170 and the second chip support structures 270, the occurrence of warpage in the package substrate 500, the first semiconductor chip 100, and the second semiconductor chips 200 included in the semiconductor package 1 may be prevented although pressure is applied between the lower jig and the upper jig after the lower jig is disposed below the package substrate 500 and the upper jig is disposed on the uppermost second semiconductor chip 200T. As a result, structural reliability and electrical connection reliability among the package substrate 500, the first semiconductor chip 100, and the second semiconductor chips 200 may be increased.

While the inventive concept has been particularly shown and described with reference to embodiments thereof, it will be understood that various changes in form and details may be made therein without departing from the spirit and scope of the inventive concept as defined by the following claims.

What is claimed is:

1. A semiconductor package, comprising:
a plurality of semiconductor chips stacked in a first direction;
a plurality of chip connection terminals disposed between two semiconductor chips disposed adjacent to each other in the first direction among the plurality of semiconductor chips and electrically connecting the two adjacent semiconductor chips; and
a plurality of chip support structures disposed between the two adjacent semiconductor chips,
wherein the plurality of chip support structures do not electrically connect the two adjacent semiconductor chips, and are spaced apart from the plurality of chip connection terminals in a second direction crossing the first direction,
wherein a thickness of each of the plurality of chip support structures is greater than a thickness of each of the plurality of chip connection terminals.

2. The semiconductor package of claim 1, wherein
each of the plurality of semiconductor chips includes a substrate, a front protective layer disposed on a lower surface of the substrate, and a rear protective layer disposed on an upper surface of the substrate, and
the plurality of chip support structures extend into a rear protective layer of a semiconductor chip disposed on a lower side among the plurality of semiconductor chips.

3. The semiconductor package of claim 2, wherein
the rear protective layer has a groove extending inwardly from an upper surface of the rear protective layer,
the groove does not pass through the rear protective layer, and
a lower portion of each of the plurality of chip support structures fills the groove.

4. The semiconductor package of claim 3, wherein the lower portion of each of the plurality of chip support structures and the groove extend from an upper side to a lower side and have a tapered shape with a decreasing horizontal width.

5. The semiconductor package of claim 3, wherein the lower portion of each of the plurality of chip support structures is downwardly convex, and the groove is inwardly concave from the upper surface of the rear protective layer.

6. The semiconductor package of claim 1, wherein
each of the plurality of chip connection terminals includes a chip conductive pillar and a chip conductive cap covering a lower surface of the chip conductive pillar, and
a horizontal width of each of the plurality of chip support structures is greater than a horizontal width of the chip conductive pillar of each of the plurality of chip connection terminals.

7. The semiconductor package of claim 1, further comprising:
a package substrate disposed below the plurality of semiconductor chips;
a plurality of substrate connection terminals disposed between a lowermost semiconductor chip among the plurality of semiconductor chips and the package substrate and electrically connecting the lowermost semiconductor chip to the package substrate; and
a plurality of substrate support structures disposed between the lowermost semiconductor chip and the package substrate,
wherein the plurality of substrate support structures do not electrically connect the lowermost semiconductor chip to the package substrate, and are spaced apart from the plurality of substrate connection terminals in the second direction,
wherein a thickness of each of the plurality of substrate support structures is greater than a thickness of each of the plurality of substrate connection terminals.

8. The semiconductor package of claim 7, wherein a horizontal width of each of the plurality of substrate support structures is greater than a horizontal width of each of the plurality of substrate connection terminals.

9. The semiconductor package of claim 7, wherein a number of the plurality of substrate support structures is greater than a number of the plurality of chip support structures disposed between the two adjacent semiconductor chips in the first direction.

10. The semiconductor package of claim 7, wherein a horizontal width of each of the plurality of substrate support structures has a greater value than a horizontal width of each of the plurality of chip support structures.

11. A semiconductor package, comprising:
a package substrate including a package base insulating layer, a lower solder resist layer covering a lower surface of the package base insulating layer, and an upper solder resist layer covering an upper surface of the package base insulating layer;
a plurality of semiconductor chips each including a substrate, a front protective layer disposed on a lower surface of the substrate, and a rear protective layer disposed on an upper surface of the substrate,
wherein the plurality of semiconductor chips includes a first semiconductor chip disposed on the package substrate and a plurality of second semiconductor chips sequentially stacked on the first semiconductor chip in a first direction;
a plurality of first chip connection terminals disposed between the package substrate and the first semiconductor chip and electrically connecting the package substrate to the first semiconductor chip;
a plurality of first chip support structures disposed between the package substrate and the first semiconductor chip,
wherein the plurality of first chip support structures are spaced apart from the plurality of first chip connection terminals in a second direction and extend into the upper solder resist layer;
a plurality of second chip connection terminals disposed between two semiconductor chips disposed adjacent to each other in the first direction among the plurality of semiconductor chips,
wherein the plurality of second chip connection terminals electrically connect the two adjacent semiconductor chips, and the second direction crosses the first direction; and
a plurality of second chip support structures disposed between the two adjacent semiconductor chips,
wherein the plurality of second chip support structures extend into the rear protective layer included in a lower semiconductor chip among the two adjacent semiconductor chips.

12. The semiconductor package of claim 11, wherein
the plurality of first chip support structures extend into the upper solder resist layer and do not penetrate through the upper solder resist layer, and
the plurality of second chip support structures extend into the rear protective layer and do not penetrate through the rear protective layer.

13. The semiconductor package of claim 12, wherein
each of the plurality of first chip support structures extends into a first groove extending inwardly from an upper surface of the upper solder resist layer,
each of the plurality of second chip support structures extends into a second groove extending inwardly from an upper surface of the rear protective layer,
a horizontal width of the first groove is greater than a horizontal width of each of the plurality of first chip support structures, and
a horizontal width of the second groove is greater than a horizontal width of each of the plurality of second chip support structures.

14. The semiconductor package of claim 11, wherein
each of the plurality of first chip connection terminals includes a first chip conductive pillar and a first chip conductive cap covering a lower surface of the first chip conductive pillar, and each of the plurality of second chip connection terminals includes a second chip conductive pillar and a second chip conductive cap covering a lower surface of the second chip conductive pillar, and
a horizontal width of each of the plurality of first chip support structures is greater than a horizontal width of the first chip conductive pillar, and a horizontal width of each of the plurality of second chip support structures is greater than a horizontal width of the second chip conductive pillar.

15. The semiconductor package of claim 14, wherein
the horizontal width of the first chip conductive pillar is about equal to the horizontal width of the second chip conductive pillar, and
the horizontal width of the first chip support structure is greater than the horizontal width of the second chip support structure.

16. The semiconductor package of claim 14, wherein a number of the plurality of first chip support structures is greater than a number of the plurality of second chip support structures.

17. The semiconductor package of claim 14, wherein the first chip conductive pillar, the second chip conductive pillar, the first chip support structure, and the second chip support structure include a same material.

18. A semiconductor package, comprising:
a package substrate including a package base insulating layer, a plurality of package upper pads disposed on an upper surface of the package base insulating layer, a plurality of package lower pads disposed on a lower surface of the package base insulating layer, a plurality of connection pads electrically connecting the plurality of package upper pads to the plurality of package lower pads, an upper solder resist layer covering the upper surface of the package base insulating layer and not covering at least a portion of an upper surface of each of the plurality of package upper pads, and a lower solder resist layer covering the lower surface of the package base insulating layer and not covering at least a portion of a lower surface of each of the plurality of package lower pads;
a plurality of semiconductor chips including a first semiconductor chip and a plurality of second semiconductor chips sequentially stacked on the package substrate in a first direction,
wherein the first semiconductor chip and the plurality of second semiconductor chips each include a substrate, a plurality of rear connection pads disposed on an upper surface of the substrate, a plurality of front connection pads disposed on a lower surface of the substrate, a plurality of through-electrodes vertically penetrating through at least a portion of the substrate and electrically connecting the plurality of rear connection pads to the plurality of front connection pads, a front protective layer disposed on the lower surface of the substrate and not covering at least a portion of a lower surface of each of the plurality of front connection pads, and a rear protective layer disposed on the upper surface of the substrate and not covering at least a portion of an upper surface of each of the plurality of rear connection pads;
a plurality of first chip connection terminals disposed between the plurality of package upper pads of the package substrate and the plurality of front connection pads of the first semiconductor chip;
a plurality of first chip support structures disposed between the package substrate and the first semiconductor chip,
wherein the plurality of first chip support structures are spaced apart from the plurality of first chip connection terminals in a second direction, extend into the upper solder resist layer, and do not penetrate through the upper solder resist layer;
a plurality of second chip connection terminals disposed between two semiconductor chips disposed adjacent to each other in the first direction among the plurality of semiconductor chips and disposed between the plurality of rear connection pads and the plurality of front connection pads facing each other included in the two adjacent semiconductor chips,
wherein the second direction crosses the first direction; and
a plurality of second chip support structures disposed between the two adjacent semiconductor chips,
wherein the plurality of second chip support structures extend into the rear protective layer included in a lower semiconductor chip among the two adjacent semiconductor chips and do not penetrate through the rear protective layer.

19. The semiconductor package of claim 18, wherein
each of the plurality of first chip connection terminals includes a first chip conductive pillar and a first chip conductive cap covering a lower surface of the first chip conductive pillar,
each of the plurality of second chip connection terminals includes a second chip conductive pillar and a second chip conductive cap covering a lower surface of the second chip conductive pillar, and
each of the first chip conductive pillar, the second chip conductive pillar, the first chip support structure, and the second chip support structure includes a metal.

20. The semiconductor package of claim 19, wherein
a horizontal width of each of the first chip conductive pillar and the second chip conductive pillar is between about 15 μm and about 40 μm, and
a horizontal width of the first chip support structure is about 5% to about 20% greater than the horizontal width of the first chip conductive pillar, and a horizontal width of the second chip support structure is about 5% to about 20% greater than the horizontal width of the second chip conductive pillar.
